(19) United States
(12) Patent Application Publication
(10) Pub. No.: US 2013/0133745 A1
(43) Pub. Date: May 30, 2013

(54) INCORPORATION OF ALKALINE EARTH IONS INTO ALKALI-CONTAINING GLASS SURFACES TO INHIBIT ALKALI EGRESS

(71) Applicants: James Patrick Hamilton, Horseheads, NY (US); Kenneth Edward Hrdina, Horseheads, NY (US)

(72) Inventors: James Patrick Hamilton, Horseheads, NY (US); Kenneth Edward Hrdina, Horseheads, NY (US)

(21) Appl. No.: 13/669,661

(22) Filed: Nov. 6, 2012

Related U.S. Application Data
(60) Provisional application No. 61/565,103, filed on Nov. 30, 2011.

(51) Int. Cl. H01L 31/0264; B32B 33/00; C03C 21/00

(52) U.S. Cl. 136/260; 65/30.13; 428/410; 136/262

(57) ABSTRACT

Leaching alkali ions from a glass substrate to form a glass substrate having an intrinsic alkali barrier layer includes providing a glass substrate comprising alkali metal ions and having at least two opposing surfaces and a thickness between the surfaces, and contacting at least one of the surfaces of the substrate with a solution comprising alkaline earth salts in either water or as a melted salt bath such that at least a portion of the alkali metal ions are replaced by alkaline earth metal ions in the at least one surface and into the thickness to form the glass substrate having an intrinsic alkali barrier layer.

This application claims the benefit of priority under 35 U.S.C. §119 of U.S. Provisional Application Ser. No. 61/565,103 filed Nov. 30, 2011, the content of which is relied upon and incorporated herein by reference in its entirety.

### FIELD

This disclosure is directed generally to glass substrates with diffusion barrier layers and more particularly to glass substrates with alkali diffusion barrier layers which may be useful in photovoltaic applications, for example, thin film photovoltaic (PV) devices and methods of making the same.

### BACKGROUND

One issue facing the PV industry today in the development of thin film solar panel technologies is controlling alkali delivery from a substrate material into a deposited semiconductor thin film. Two exemplary PV thin film technologies in development today are Cadmium Telluride (CdTe) and Cadmium Indium Gallium Selenide (CIGS). In the case of CdTe, the thin film stacks are deposited onto the glass superstrate through which sunlight must pass. It has been established that incorporation of alkali ions into the transparent conducting oxide (TCO) and/or CdTe thin films can degrade the device's efficiency in converting sunlight into electricity. The most common barrier layers currently employed in the CdTe thin film stack are sputter-deposited silica (SiO₂) or alumina (Al₂O₃). These barrier layers can suppress the egress of alkali ions from the glass superstrate, but not completely block it.

It would be advantageous to have an alkali metal barrier layer which is intrinsic to the glass instead of a separate layer which is extrinsic to the glass.

### SUMMARY

Additional features and advantages will be set forth in the detailed description which follows, and in part will be readily apparent to those skilled in the art from the description or recognized by practicing the invention as described in the written description and claims hereof.

The disclosure identifies a surface enriched in divalent alkaline earth ions such as Ca²⁺, Mg²⁺, Sr²⁺, and/or Ba²⁺ that serve to inhibit alkali migration out of the underlying substrate. This enriched surface layer is created by ion-exchange with alkaline earth salts in either water or as a melted salt bath. In the case of ion-exchangeable glass, alkaline earth ions are known to block or greatly inhibit further ion-exchange processes. Calcium contaminants within the molten salt bath have been identified as “poisoning” the ion-exchange process. In that process, the presence of calcium is undesirable. Embodiments take advantage of this diffusion inhibition characteristic to block or reduce the release of alkali ions from the material surface. The substrate material is primarily envisioned as being an alkali-containing glass, but could also be a ceramic with a glass phase containing alkali.

The exact mechanism by which calcium inhibits ion-exchange is not precisely known and should not limit this disclosure. However, it is well known that addition of calcium to binary alkali-silicate glasses improves chemical durability in terms of both reduced alkali release (leach) rate and slower dissolution (breakdown of the silicate glass network that causes release of silica into solution). Similar improvement in chemical durability has been observed with the addition of other alkaline earth ions (Mg, Sr, Ba) to binary alkali-silicate glasses. The addition of calcium and other alkaline earth ions to binary silicate glasses is also known to reduce electrical conductivity. These three observed behaviors are likely interrelated by the effect that alkaline earth ions have on the mobility of alkali ions within the glass network. Divalent calcium ions (Ca²⁺) have much higher field strength than monovalent sodium ions (Na⁺). As a result, calcium ions form stronger bonds with the non-bridging oxygen ions that they serve to charge compensate than sodium ions.

Additionally, each divalent calcium ion charge balances two nearby non-bridging oxygen ions whereas each monovalent sodium ion only charge balances a single non-bridging oxygen ion. In this way, calcium ions tend to more effectively link the silicate glass network than sodium ions. The higher field strength of calcium ions tends to pull the surrounding oxygen atoms closer to themselves than sodium ions, which results in a glass network structure with lower free volume and consequently, less space for ions to move. The stronger bonds between calcium and non-bridging oxygen ions compared to those between sodium and non-bridging oxygen ions result in greater hydrolytic stability of the glass network as a whole. For this reason, replacement of sodium ions by calcium ions in simple silicate glasses can improve resistance to chemical attack by water. As an example, soda-lime-silicate glasses are significantly more durable than sodium-silicate glasses. Penetration of water or hydronium ions into the glass network and subsequent out diffusion of sodium ions is hindered by the lower free volume and higher average bond strength created by the presence of calcium. This reasoning generally applies to the substitution of any alkaline earth ion for an alkali ion in relatively simple silicate glasses, but the extent of the effect on ion mobility depends on the specific substitution made and the presence of more than one type of alkali or alkaline earth ion (i.e., mixed alkali effect).

One embodiment is a method of leaching alkali ions from a glass substrate to form a glass substrate having an intrinsic alkali barrier layer, the method comprising:
providing a glass substrate comprising alkali metal ions and having at least two opposing surfaces and a thickness between the surfaces; and
contacting at least one of the surfaces of the substrate with a solution comprising alkaline earth salts in either water or as a melted salt bath such that at least a portion of the alkali metal ions are replaced by alkaline earth metal ions in the at least one surface and into the thickness to form the glass substrate having an intrinsic alkali barrier layer.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is a secondary ion mass spectrometry (SIMS) profile of glass that had been placed in a molten salt composed of 60 wt % Ca(NO₃)₂ and 40 wt % KNO₃.

FIG. 2 is an illustration of features of a photovoltaic device according to one embodiment.

### DETAILED DESCRIPTION

Reference will now be made in detail to various embodiments of the invention.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module. Photovoltaic device can describe either a cell, a module, or both.

As used herein, the term “adjacent” can be defined as being in close proximity. Adjacent structures may or may not be in physical contact with each other. Adjacent structures can have other layers and/or structures disposed between them.

One embodiment is a method of leaching alkali ions from a glass substrate to form a glass substrate having an intrinsic alkali barrier layer, the method comprising:
providing a glass substrate comprising alkali metal ions and having at least two opposing surfaces and a thickness between the surfaces; and
contacting at least one of the surfaces of the substrate with a solution comprising alkaline earth salts in either water or as a melted salt bath such that at least a portion of the alkali metal ions are replaced by alkaline earth metal ions in the at least one surface and into the thickness to form the glass substrate having an intrinsic alkali barrier layer.

In some embodiments, glass surface(s) have been engineered by an ion-exchange process to prevent or reduce alkali egress from the bulk glass without significantly altering the bulk properties of the glass (aka, barrier layer).

The chemical composition of the ion-exchanged surface layer is enriched in alkaline earth ion(s) (e.g., Ca, Mg, Sr, Ba, etc.), and in some cases silver, aluminum or lead, relative to the bulk glass composition. The enriched surface layer must consist of the primary elements that constitute the glass network. In the case of silicate glasses, these elements include at least silicon and oxygen but may or may not include other network-forming elements such as boron, aluminum, zirconium, germanium, phosphorus, etc.

The compositional range of alkaline earth ions in the surface layer can be from about 0.1 to 40 wt %, for example, 0.2 to 40 wt %, for example, 0.3 to 40 wt %, for example, 0.4 to 40 wt %, for example, 0.5 to 40 wt %, for example, 0.6 to 40 wt %, for example, 0.7 to 40 wt %, for example, 0.8 to 40 wt %, for example, 0.9 to 40 wt %, for example, 1 to 40 wt %, for example, 1.1 to 40 wt %, for example, 1.2 to 40 wt %, for example, 1.3 to 40 wt %, for example, 1.4 to 40 wt %, for example, 1.5 to 40 wt %, for example, 1.6 to 40 wt %, for example, 1.7 to 40 wt %, for example, 1.8 to 40 wt %, for example, 1.9 to 40 wt %, for example, 2.0 to 40 wt %, for example, 2.1 to 40 wt %, for example, 2.2 to 40 wt %, for example, 2.3 to 40 wt %, for example, 2.4 to 40 wt %, for example, 2.5 to 40 wt %, for example, 2.6 to 40 wt %, for example, 2.7 to 40 wt %, for example, 2.8 to 40 wt %, for example, 2.9 to 40 wt %, for example, 3 to 40 wt %, or, for example, 0.1 to 39 wt %, for example, 0.1 to 38 wt %, for example, 0.1 to 37 wt %, for example, 0.1 to 36 wt %, for example, 0.1 to 35 wt %, for example, 0.1 to 34 wt %, for example, 0.1 to 33 wt %, for example, 0.1 to 32 wt %, for example, 0.1 to 31 wt %, for example, 0.1 to 30 wt %, for example, 0.1 to 29 wt %, for example, 0.1 to 28 wt %, for example, 0.1 to 27 wt %, for example, 0.1 to 26 wt %, for example, 0.1 to 25 wt %, for example, 0.1 to 24 wt %, for example, 0.1 to 23 wt %, for example, 0.1 to 22 wt %, for example, 0.1 to 21 wt %, for example, 0.1 to 20 wt %, or, for example, 1 to 40 wt %, for example, 1 to 39 wt %, for example, 1 to 38 wt %, for example, 1 to 37 wt %, for example, 1 to 36 wt %, for example, 1 to 35 wt %, for example, 1 to 34 wt %, for example, 1 to 33 wt %, for example, 1 to 32 wt %, for example, 1 to 31 wt %, for example, 1 to 30 wt %, for example, 1 to 29 wt %, for example, 1 to 28 wt %, for example, 1 to 27 wt %, for example, 1 to 26 wt %, for example, 1 to 25 wt %, for example, 1 to 24 wt %, for example, 1 to 23 wt %, for example, 1 to 22 wt %, for example, 1 to 21 wt %, for example, 1 to 20 wt %. In some embodiments, the barrier layer is greater in at least one of the alkaline earth, silver, lead or aluminum concentrations than that of the bulk glass.

In some embodiments, glass surface(s) have been engineered to create two layers by a combination of ion-exchange and leaching processes to prevent or reduce alkali egress from the bulk glass without significantly altering the bulk properties of the glass.

The first, innermost surface layer (adjacent to the bulk glass) is enriched in alkaline earth ion(s) (e.g., Ca, Mg, Sr, Ba, etc.), and in some cases silver, aluminum or lead, relative to the bulk glass composition. The enriched surface layer comprises primary elements that constitute the glass network. In the case of silicate glasses, these elements include at least silicon and oxygen but may or may not include other network-forming elements such as boron, aluminum, zirconium, germanium, phosphorus, etc.

The second, outermost surface layer (adjacent to the initial ion-exchanged surface layer) is depleted in alkali and/or alkaline earth ions by leaching of the original ion-exchanged surface layer. In some embodiments, the thickness of the outermost leached surface layer is smaller than the thickness of the original ion-exchanged surface layer. In some embodiments, an average thickness of 5 nm for the original ion-exchanged surface layer is retained between the bulk glass and leached surface layer. In some embodiments, that the outermost leached surface layer thickness is smaller than that of the retained ion-exchanged surface layer (for example, at least 50% of the original ion-exchanged surface layer thickness can be retained after completion of the leaching process). The primary purpose of the secondary leaching process is to extract any residual alkali metal ions that were incorporated into the glass surface layer during the original ion-exchange process and to minimize egress of alkali metal ions from the glass surface.

The composition of the leached surface layer is depleted in alkali (Li, Na, K, Rb, Cs, etc.) and/or alkaline earth ions (Mg, Ca, Sr, Ba, etc.) and may or may not be enriched in hydrogen relative to the bulk glass composition. The range of alkali or alkaline earth depletion in this 2^{nd} layer can range from about 1 to 100 wt %. The exact form or forms of hydrogen within the surface layer is not precisely known. The leached surface layer must also comprise the primary elements that constitute the glass network. In the case of silicate glasses, these elements include at least silicon and oxygen but may or may not include other network-forming elements such as boron, aluminum, zirconium, germanium, phosphorus, etc.

The leached surface layer can also be subjected to various thermal treatments (e.g., annealing in a furnace or flame polishing) in order to dehydrate and/or consolidate (densify) the surface layer.

Glass surface(s) have been engineered to create two intrinsic layers by a combination of two separate ion-exchange processes. The first ion-exchange process being a glass strengthening process known to those skilled in the art (i.e., exchange of smaller alkali ions by larger alkali ions). The second process being predominantly the exchange of alkaline earth ions (or other blocking ions such as silver, lead or aluminum) for alkali ions in the glass to reduce alkali egress from the bulk glass without significantly altering the bulk properties of the glass (aka, barrier layer).

The first, innermost surface layer (adjacent to the bulk glass) is ion-exchanged via standard alkali exchange processes known to those skilled in the art. As a common example, larger potassium ions are exchanged for smaller sodium ions in a molten salt bath such as potassium nitrate-rich salts creating compressive stress and depth of layer on the surfaces known by those skilled in the art. This ion-exchanged surface layer is enriched in potassium and depleted in sodium relative to that of the bulk glass composition.

The second, outermost surface layer (adjacent to the initial ion-exchanged surface layer) can be formed by an additional separate ion-exchange process and can be enriched in alkaline earth ions relative to that of the bulk glass composition.

In some embodiments, the thickness of the outermost alkaline earth-enriched, ion-exchanged surface layer does not exceed that of the original alkali-rich, ion-exchanged surface layer. In some embodiments, the outermost alkaline earth-enriched surface layer thickness does not exceed that of the retained alkali-rich surface layer (i.e., at least 50% of the original alkali-rich surface layer thickness can be retained after completion of the secondary ion-exchange process).

In some embodiments, the method comprises ion-exchange with alkaline earth salts in either water and/or as a melted salt bath. The method comprises dipping or submerging the glass or at least a surface of the glass in the salt or aqueous salt solution and holding the glass or glass surface within the bath for a period of time. The hold time can be from 1 second to 1 week, for example, 1 minute to 6 hours.

In some embodiments, the aqueous temperature is from 0 to 150° C., for example, from 20 to 100° C. Alternatively, if pure salts are used, then temperatures at which the salts are molten are preferred such as temperature greater than 300° C.

In some embodiments, ambient pressure is used but various pressures are possible. Higher pressures may be advantageous if aqueous solutions are used at bath temperature greater than 100° C. Aqueous solutions can comprise nitrates, chlorides, hydroxides, oxalates, or combinations thereof.

Molten salt baths can comprise nitrates such as calcium nitrate or mixtures of calcium nitrate and potassium nitrates and may lower the salt bath melting point. In some embodiments, calcium nitrate concentrations in the salt bath can range from 0.01 wt % to 100 wt %, for example, from 0.02 and 100 wt %.

The depth of alkaline earth enrichment can range from 1 nm to 5 μm, for example, 100 nm to 5 μm, for example, 200 nm to 5 μm, for example, 300 nm to 5 μm, for example, 400 nm to 5 μm, for example, 500 nm to 5 μm, for example, 600 nm to 5 μm, for example, 700 nm to 5 μm, for example, 800 nm to 5 μm, for example, 900 nm to 5 μm, for example, 1 μm to 5 μm.

The ion-exchange or combination of ion-exchange and leaching processes are amenable to a wide range of glass compositions including, but not limited to, silicates, phosphates, borates, and germanates. The ion-exchange process is most suited to alkali-alkaline earth-silicates, alkali-alkaline earth-aluminosilicates and alkali alkaline-earth-boroaluminosilicates.

In some embodiments, the glass that has been enriched with alkaline earth ions (or other block species such as silver, lead or aluminum), with or without treatment by a secondary leaching process, has improved chemical durability relative to an untreated glass.

In some embodiments, the surface layer has an electrical resistivity that is equal to or higher than that of the bulk glass.

In some embodiments, the method further comprises a secondary leaching step. The secondary leaching step is expected to result in a structure whose mechanical properties are equal to or better than untreated glass. It is expected that the surface layer will inhibit crack initiation and improve fracture toughness relative to an untreated piece of glass. In some embodiments, the thickness of the secondary alkaline-earth ion-exchanged layer relative to the alkali-rich ion-exchanged layer is minimized and may maximize the amount of strength retention. A secondary leaching step may result in a structure that imparts additional potential advantageous optical properties.

The intrinsic barrier layers do not significantly impede the transmission of light, which is advantageous for CdTe thin films where light transmits through the barrier layer. Further, the optical surface may have enhanced antireflective properties relative to an untreated glass surface.

On embodiment is a glass having an intrinsic alkali barrier layer. The glass can be made according to methods described herein.

Another embodiment is a semi-conductor device comprising the glass substrate having an intrinsic alkali barrier layer.

Another embodiment is a thin-film device comprising the glass substrate having an intrinsic alkali barrier layer.

The glass substrate having an intrinsic alkali barrier layer can be used in electronic applications (and the fully assembled electronic devices themselves). Examples include, but are not limited to, LCD displays.

Another embodiment is a photovoltaic device comprising the glass substrate having an intrinsic alkali barrier layer.

The photovoltaic device can comprise a functional layer comprising copper indium gallium diselenide or cadmium telluride adjacent to the barrier layer.

Surface barrier layers created by these processes neither allows significant alkali egress from the bulk glass, nor attracts significant alkali from subsequently deposited thin films. This can allow for a controlled amount of alkali delivery from external dopant layers.

In one embodiment, as shown in FIG. 2, features 101 of a photovoltaic device comprise the glass substrate 14 having an intrinsic alkali barrier layer 18 made according to methods described herein. The photovoltaic device can comprise more than one of the glass substrates, for example, as a substrate and/or as a superstrate. In one embodiment, the photovoltaic device 101 comprises the glass sheet as a substrate and/or superstrate 14, a conductive material 16 adjacent to the substrate, and an active photovoltaic medium 20 adjacent to the conductive material. In one embodiment, the active photovoltaic medium comprises a CIGS layer. In one embodiment, the active photovoltaic medium comprises a cadmium telluride (CdTe) layer. In one embodiment, the photovoltaic device comprises a functional layer comprising copper indium gallium diselenide or cadmium telluride. In one embodiment, the photovoltaic device the functional layer is copper indium gallium diselenide. In one embodiment, the functional layer is cadmium telluride.

In CIGS, a molybdenum back contact conducting layer may be deposited directly onto the glass surface (adjacent to the barrier layer) and in between the CIGS functional layer. This moly film would be layer 16 in FIG. 2.

In one embodiment, the barrier layer is adjacent to a transparent conductive oxide (TCO) layer, wherein the TCO layer is disposed between or adjacent to the functional layer and the barrier layer. A TCO may be present in a photovoltaic device comprising a CdTe functional layer.

In one embodiment, the glass sheet is optically transparent. In one embodiment, the glass sheet as the substrate and/or superstrate is optically transparent.

According to some embodiments, the glass sheet has a thickness of 4.0 mm or less, for example, 3.5 mm or less, for example, 3.2 mm or less, for example, 3.0 mm or less, for example, 2.5 mm or less, for example, 2.0 mm or less, for example, 1.9 mm or less, for example, 1.8 mm or less, for example, 1.5 mm or less, for example, 1.1 mm or less, for example, 0.5 mm to 2.0 mm, for example, 0.5 mm to 1.1 mm, for example, 0.7 mm to 1.1 mm. Although these are exemplary thicknesses, the glass sheet can have a thickness of any numerical value including decimal places in the range of from 0.1 mm up to and including 4.0 mm.

An advantage of some embodiments over sputter-deposited barrier layers is that the ion-exchanged layers (with our without treatment by a secondary leaching process) are intrinsic to the glass as an extension of the bulk glass structure. This may minimize any issues of adhesion or delamination due to the absence of a sharp interface between the surface layer and bulk glass. Another advantage can be that barrier layers are created uniformly and on all sides of the glass article, which is not possible with a sputtering process. As a result, chemical durability of the glass sheet may be significantly improved on all surfaces that minimize alkali and/or alkaline-earth egress over long exposure times to the environment (particularly water vapor). This protection scheme can improve electrical reliability of PV modules and enable better retention of photoconversion efficiency over the module's lifetime. A third advantage of the alkaline earth ion-exchange process is that it is a simple process that does not require complicated and expensive vacuum equipment, and is therefore, more amenable to a manufacturing operation. Finally, methods described herein may provide a methodology for engineering glass surfaces to control alkali delivery and removes this constraint on the bulk glass composition. This may increase the glass compositional space that can be employed to optimize other glass attributes such as CTE, strain point, melting, forming, cost, etc.

### EXAMPLE

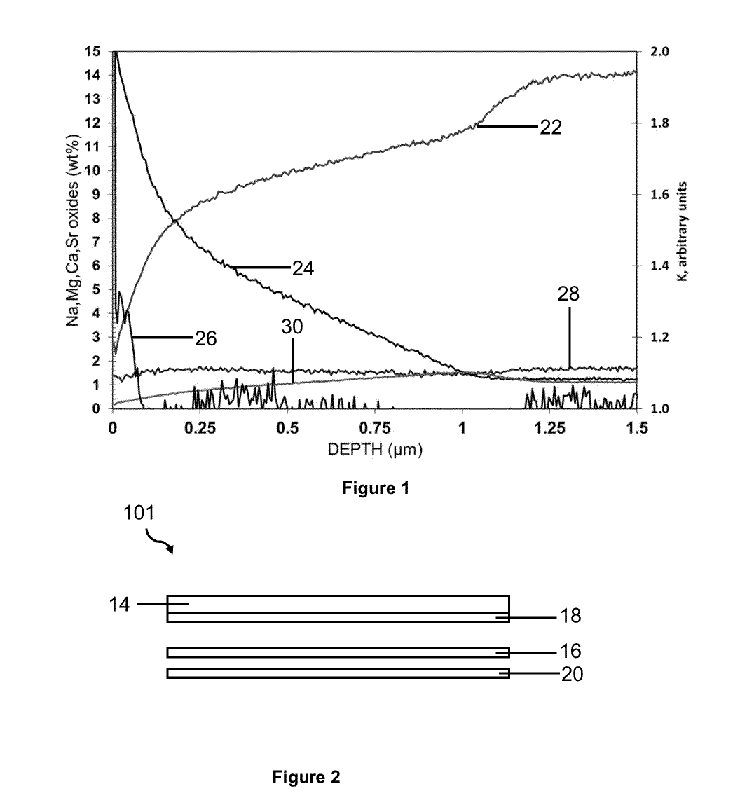

90 grams of technical grade potassium nitrate was mixed with 193 grams of Ca(NO₃)₂.4H₂O as a powder within a stainless steel beaker. The powder was next placed in a furnace at 420° C. and held at temperature for 1 week, stirring occasionally. Next, a piece of glass was preheated in the oven at 420° C. for 1 minute and then placed in the salt bath and held for a period of 5.5 hours. It was removed from the bath, allowed to cool and rinsed in deionized (DI) water. The compressive stress/depth of layer (CS/DOL), measured with a surface stress meter (FSM-6000) showed no appreciable change in CS/DOL suggesting that the calcium did serve to inhibit and impede ion-exchange. The sample was then submitted for SIMS with the results shown in FIG. 1. It shows that significant calcium enrichment, line 24, and corresponding sodium depletion, line 22, has occurred to a depth of about 1 micron with very little potassium contamination, line 26, to a depth of about 100 nm (shown on the right x axis). Lines 28 and 30 show magnesium, and strontium, respectively.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A method of leaching alkali ions from a glass substrate to form a glass substrate having an intrinsic alkali barrier layer, the method comprising:
providing a glass substrate comprising alkali metal ions and having at least two opposing surfaces and a thickness between the surfaces; and
contacting at least one of the surfaces of the substrate with a solution comprising alkaline earth salts in either water or as a melted salt bath such that at least a portion of the alkali metal ions are replaced by alkaline earth metal ions in the at least one surface and into the thickness to form the glass substrate having an intrinsic alkali barrier layer.

2. The method according to claim 1, wherein the at least one surface is enriched in a divalent alkaline earth ion selected from the group consisting of Ca²⁺, Mg²⁺, Sr²⁺, and Ba²⁺.

3. The method according to claim 1, wherein the at least one surface is enriched in silver, aluminum, lead, or a combination thereof.

4. The method according to claim 1, further comprising contacting the glass substrate having an intrinsic alkali barrier layer with a solution comprising a hydrogen bearing species such that at least a portion of the hydrogen bearing species replaces at least a portion of the alkali metal ions, alkaline earth metal ions, or the combination thereof in the at least one surface and into the thickness to form the glass substrate having an intrinsic alkali barrier layer and a leached layer.

5. The method according to claim 4, wherein the solution is an aqueous solution.

6. The method according to claim 4, wherein the solution comprises an organic solvent.

7. The method according to claim 4, wherein the solution has a temperature in the range of from 20° C. to 200° C.

8. The method according to claim 4, wherein the contacting comprises submerging the substrate in the solution.

9. The method according to claim 4, wherein the hydrogen bearing species comprises hydroxyls (OH⁻), protons (H⁺), hydronium ions (H₃O⁺), or molecular water (H₂O).

10. The method according to claim 4, further comprising heat treating the glass substrate having a barrier layer after the contacting.

11. The method according to claim 1, wherein the glass substrate is an aluminosilicate glass.

12. A glass having an intrinsic alkali barrier layer made according to claim 1.

13. A semi-conductor device comprising the glass substrate having an intrinsic alkali barrier layer made according to claim 1.

14. A thin-film device comprising the glass substrate having an intrinsic alkali barrier layer made according to claim 1.

15. A photovoltaic device comprising the glass substrate having an intrinsic alkali barrier layer made according to claim 1.

16. The photovoltaic device according to claim 15, comprising a functional layer comprising copper indium gallium diselenide or cadmium telluride adjacent to the barrier layer.
